(19) United States
(12) Patent Application Publication
(10) Pub. No.: US 2022/0406590 A1
(43) Pub. Date: Dec. 22, 2022

(54) METHOD AND CARRIER ELEMENT FOR PRODUCING A WAFER LAYER

(71) Applicant: NexWafe GmbH, Freiburg (DE)

(72) Inventors: Stefan REBER, Gundelfingen (DE); Nena MILENKOVIC, Reute (FR); Kai SCHILLINGER, Freiburg (DE)

(73) Assignee: NexWafe GmbH, Freiburg (DE)

(21) Appl. No.: 17/776,648

(22) PCT Filed: Oct. 15, 2020
(86) PCT No.: PCT/EP2020/079032

§ 371 Date: May 13, 2022

(30) Foreign Application Priority Data
Nov. 14, 2019 (DE) 102019130745.7

(51) Int. Cl. H01L 21/02; H01L 21/20

(52) U.S. Cl. CPC H01L 21/02002; H01L 21/20

(57) ABSTRACT

A method for producing a wafer layer, including the method steps of: A) providing a carrier element; B) making the carrier element porous on at least one surface in order to produce a separating layer; C) applying a wafer layer to the separating layer of the carrier element by epitaxy; and D) detaching the wafer layer from the carrier element, with method steps B to D being repeated at least once, preferably multiple times, with the carrier element. The method step A includes the additional method steps of: A1) providing a carrier substrate; and A2) applying a seed layer to at least one surface and at least one lateral face of the carrier substrate by epitaxy in order to produce the carrier element. A carrier element for producing a wafer layer and an intermediate product are also provided.

### TECHNICAL FIELD

The invention relates to a method of producing a wafer layer and to a carrier element for production of a wafer layer.

### BACKGROUND

For large-area electronic components, for example large-area lighting elements or photovoltaic solar cells, but also for mass-produced products, for example semiconductor diodes, there is a need for inexpensive semiconductor wafers having high electrical quality, since, in the case of such components, the material costs of the semiconductor wafer constitute a significant proportion of the costs of the overall product. There are known methods of producing semiconductor wafers wherein semiconductor wafers are produced from silicon blocks (“ingots”) by means of sawing methods. In this way, it is possible to produce high-quality, especially monocrystalline, semiconductor wafers. However, production costs are high, one reason for which is the loss of material in the sawing of the silicon blocks.

Therefore, alternative methods have been developed, in which a wafer layer is deposited on a carrier element and then detached from the carrier element. The wafer layer detached thus constitutes the semiconductor wafer for production of the electronic component.

It is known from the prior art to form a porous separation layer on part of the carrier substrate surface and then to deposit a wafer layer on the carrier substrate in an epitaxial process. For detachment of the wafer layer from the carrier substrate, separation steps are conducted by means of a laser beam, which fully penetrate the semiconductor layer and at least partly extend into the separation layer or carrier substrate.

However, it has been found to be disadvantageous that parts of the wafer layer remain on the carrier substrate in the edge region of the carrier substrate, which are sometimes difficult to remove. Furthermore, the separation steps also affect the carrier substrate or separation layer, such that the carrier substrates often cannot be reused for production of a further wafer layer or have to be processed in a complex manner, but this limits reusability.

An optimization of the known method of producing a semiconductor layer is known, for example, from DE 102015118042 A1. In this case, a separation layer is formed on at least one processing face of the carrier substrate prior to the application of the wafer layer, and the wafer layer is applied in an overlapping manner on the processing face and on at least one edge face of the carrier substrate, with removal of the overlapping regions of the wafer layer prior to the removal of the wafer layer from the carrier substrate.

By virtue of the overlapping application, the wafer layer can be detached completely from the separation layer or carrier substrate. It is important for the reusability of the carrier substrate that the carrier substrate after the detachment no longer has any residues of the wafer layer. In order to ensure this, it is necessary also to trim the carrier substrate in the removal of the overlapping regions and to remove a few micrometers, and so the lateral dimensions of the carrier substrate are reduced after each use. As soon as the dimensions of the carrier substrate go below a minimum dimension, it can no longer be used as carrier substrate for the production of further wafer layers.

For industrial use, a reduction in costs is necessary in the production of the wafer layers, especially by the reusability of carrier substrates.

### SUMMARY

It is an object of the present invention to increase the reusability of carrier substrates and to achieve a reduction in costs in the production of a wafer layer.

It is a further object of the present invention to further improve quality in the production of a wafer layer, especially to reduce errors induced by the carrier substrate or separation layer.

These and further objects are achieved by a method of producing a wafer layer having one or more of the features described herein, by a carrier element for production of a wafer layer having one or more of the features described herein, and by an intermediate product having one or more of the features described herein. Advantageous configurations of the method and the carrier element for production of a wafer layer can be found in the description and claims that follow.

The method of the invention for production of a semiconductor layer has the following method steps:

A first method step A comprises the providing of a carrier element. In a method step B, the carrier element is porosified on at least one surface of the carrier element for creation of a separation layer. More particularly, the porosifying can result in formation of the carrier layer at least partly along one or more lateral faces of the carrier element as well. In a method step C, a wafer layer is applied to the separation layer of the carrier element by means of epitaxy. In a further method step D, the wafer layer is detached from the carrier element. It is a further feature of the method that method steps B to D are repeated at least once, preferably more than once, with the carrier element.

The detached wafer layer especially finds use in the production of an electronic component, and is especially used for production of a photovoltaic solar cell.

It is a feature of the method according to the invention that method step A comprises the further method steps A1 and A2, wherein, in method step A1, a carrier substrate is provided, and, in method step A2, a seed layer is applied to at least one surface and at least one lateral face of the carrier substrate by means of epitaxy for production of the carrier element.

It has been found, more particularly, that the method of the invention allows repeated use of the carrier element for the production of wafer layers without experiencing losses in respect of the quality of the wafer layer.

More particularly, the method of the invention enables more frequent use of the carrier substrate compared to the prior art, since the epitaxial seed layer and the carrier layer are restorable on the carrier substrate. If a minimum dimension of the carrier element is attained, with the minimum dimension of the carrier element corresponding at least to the dimensions of the carrier substrate, the seed layer can be applied again by means of epitaxy on the carrier substrate, and the carrier element can be reprocessed. This is enabled especially in that the carrier substrate, throughout the process, is altered only to a minor degree, if at all, in terms of its quality and its properties, especially its dimensions.

Moreover, the method of the invention enables adjustment of the carrier element, especially the epitaxial seed layer, to the necessary properties for the further method steps such as the porosification. Thus, there is no need for any specific, often costly, carrier substrates that often have lower quality by virtue of their specific properties.

More particularly, the epitaxial layer has higher quality and homogeneity, especially in relation to the crystal structure and electronic properties, compared to a carrier substrate produced in a zone melting or crystal growing method.

The frequent use of the carrier substrate in production for a multitude of wafer layers especially makes it possible to use very high-quality carrier substrates, especially in relation to crystal quality and the surface. Defects in the crystal structure and/or the surface of the carrier substrate have a direct effect on the quality of the epitaxial seed layer and the wafer layer. More particularly, it is possible for further defects in the crystal structure of the seed layer and wafer layer to be induced by defects in the crystal structure and/or the surface of the carrier substrate.

High-quality carrier substrates thus permit higher quality in the application of further layers by means of epitaxy, and enable a higher process yield. More particularly, the higher costs for high-quality carrier substrates are paid for by the frequent use and reprocessing of the carrier elements based thereon for the production of wafer layers, such that it is possible to achieve a reduction in costs overall in the production of the wafer layers.

In an advantageous manner, method steps B to D are performed with one carrier element at least 10 times, preferably at least 20 times, more preferably at least 30 times.

More particularly, a carrier element comprising a carrier substrate and an epitaxial seed layer may be used for production of wafer layers until the dimension of the carrier element is equal to or slightly lower than a defined minimum dimension, especially preferably by less than 10 μm, more preferably by less than 5 μm, most preferably by less than 3 μm.

The minimum dimension is based on the dimension of the carrier element in lateral direction and especially preferably also in vertical direction.

More particularly, the dimension of the carrier substrate in lateral direction and especially preferably in vertical direction may be a minimum dimension for the carrier element.

In an advantageous manner, the carrier element can be reprocessed when the dimension of the carrier element is equal to or lower than the minimum dimension, and then used further as carrier element for the production of wafer layers.

Preference is given to reprocessing the carrier element by performing method step A2 with the carrier substrate used beforehand.

Before performing method step A2 again on an already utilized carrier element, this carrier element of the carrier substrate may be subjected to a first processing operation, such that the formation of a high-quality seed layer on the carrier element that was already in use is again enabled.

More particularly, the carrier element provided for reuse, or the carrier substrate, may be processed prior to method step A2 by mechanical treatment such as polishing or grinding or chemical treatment such as etching or a combination of chemical and mechanical treatment, such that it especially has a high-quality surface on which the seed layer is subsequently applied.

The reprocessing of the carrier element achieves use of an original carrier substrate many times more frequently in the production of wafer layers. More particularly, by virtue of the use many times more frequently, it is possible to utilize high-quality carrier substrates, which simultaneously also increases the quality of the wafer layers. Even though higher costs are associated with a high-quality carrier substrate, the costs for the production of the individual wafer layer are lowered by virtue of the use of the carrier substrate many times more frequently, especially by virtue of the reprocessing of the carrier element comprising the carrier substrate.

The epitaxy of the seed layer and of the wafer layer are preferably conducted in the same epitaxy apparatus. Alternatively, the seed layer and the wafer layer may also be conducted in different epitaxy apparatuses.

Preferably, a carrier substrate is used in a carrier element for production of at least 50, preferably of at least 100, more preferably at least 150, wafer layers.

More particularly, the carrier substrate may have a smoothly ground or polished surface. The quality of the epitaxial layer and of the wafer layer may thus be improved even further.

Overall, the method of the invention can improve the quality of the wafer layers, especially in relation to the crystal structure and the electronic properties, and the costs in production can simultaneously be lowered by the reusability and restorability of the carrier element.

The epitaxial seed layer and epitaxial wafer layer are applied by means of chemical or physical gas phase deposition or mixed forms thereof. More particularly, the seed layer and wafer layer are preferably applied by means of chemical gas phase epitaxy. Epitaxy enables the production of high-quality layers, especially in relation to the crystal structure and low introduction of extraneous matter.

The separation layer preferably takes the form of a porous layer, in a manner known per se. More particularly, for production of the separation layer, the carrier substrate is advantageously porosified in a manner known per se, especially by means of an etching operation, as described, for example, in DE 102013219839 A1.

In a preferred configuration of the method, the seed layer is applied so as to ensheath the one surface and all lateral faces of the carrier substrate.

It is thus possible to provide a uniform, especially homogeneous, face composed of a material as a nucleation layer for the production of the wafer layer, and to avoid defect-causing sites outside the seed layer, especially on the carrier substrate.

In addition, ensheathing of the carrier substrate on at least one surface and all lateral faces makes it possible to avoid inhomogeneities during the porosification in method step B.

More particularly, the seed layer can be applied to all surfaces and all lateral faces of the carrier substrate and can fully ensheath the carrier substrate. The carrier substrate is thus completely surrounded by the seed layer.

Another advantage has been found to be that ensheathing of the carrier substrate on at least one surface and all lateral faces can protect the carrier substrate from damage and hence further increase reusability.

An advantageous configuration of the method has the feature that the carrier substrate and the seed layer have been formed from or are formed from silicon, germanium or gallium arsenide.

Silicon is available in a high quality in large volumes and also for large-area applications, and so the use of silicon is especially suitable for the carrier substrate. The seed layer on a carrier layer composed of silicon is preferably formed from silicon as well, in order to form a carrier element composed of one material.

The carrier substrate is preferably only weakly doped.

Weakly doped carrier substrate can be produced with a high quality since weak doping, aside from the actual dopant element, introduces only a small amount of extraneous matter that especially leads to defects in the lattice structure of the carrier substrate, and can induce further defects in the structure of the epitaxial seed layer.

In an alternative embodiment of the method, the carrier substrate is n-doped or p-doped, where the dopant concentration is in the region of less than 5×10¹⁹ cm⁻³, preferably in the region of less than 1×10¹⁸ cm⁻³, more preferably in the region of less than 1×10¹⁷ cm⁻³, most preferably in the region of less than 5×10¹⁵ cm⁻³.

A low dopant concentration of the carrier substrate within the aforementioned range allows a positive influence on the properties of the seed layer, especially when the seed layer is doped with the same dopant element, but usually with a higher dopant concentration.

The carrier substrate, by virtue of the lower dopant concentration, preferably also has a lower concentration of other impurities, and so the seed layer and the wafer layer have a lower concentration of impurities and hence a higher layer quality.

In an advantageous manner, the dopant elements boron, phosphorus, gallium or arsenic are used for doping of a carrier substrate composed of silicon or germanium.

The conductivity of the carrier substrate is especially below a value of 10 ohm cm. The conductivity of the carrier substrate is preferably within a range between 2 mohm cm and 3000 mohm cm, preferably within a range from 10 mohm cm to 200 mohm cm, especially around 100 mohm cm.

A preferred embodiment of the invention has the feature that the seed layer is applied on the at least one surface of the carrier substrate with a layer thickness in the range from 10 μm to 250 μm, preferably in the range from 25 μm to 100 μm, more preferably in the range from 40 μm to 80 μm.

Alternatively or additionally, the seed layer is applied on the at least one lateral face of the carrier substrate with a layer width in the range from 10 μm to 600 μm, preferably in the range from 25 μm to 400 μm, more preferably in the range from 50 μm to 250 μm.

On detachment of the wafer layer from the carrier element, especially as a result of the trimming of the wafer layer to be detached and of the porosification of the carrier element, there may be a reduction in the layer thickness and layer width. An appropriate layer thickness permits the performance of a multitude of cycles of method steps B to D for production of a wafer layer with the same carrier layer until attainment of the minimum dimensions of the carrier element.

More particularly, the seed layer is applied with a greater layer width than layer thickness.

For reuse of the carrier element, it is necessary for the forming of a further wafer layer to be preceded by complete detachment of the wafer layer applied beforehand. For assurance of the complete detachment of the wafer layer from the carrier element, it is therefore usually necessary, in each detachment of the wafer layer, also to trim the carrier element slightly, especially within a range from 2 μm to 20 μm.

On each detachment of a wafer layer from the carrier element, the dimensions of the carrier element are reduced slightly, especially within a range from 2 μm to 20 μm. However, it has been found that the layer width on detachment of the wafers is usually reduced more significantly than the layer thickness. A greater layer width therefore enables a greater number of the cycles of method steps B to D before the minimum dimensions are achieved both in terms of layer width and in terms of layer thickness.

A greater layer width than layer thickness further enables performance, with greater tolerance and correspondingly less costly equipment, of the trimming of the edges of the wafer layer in order also to remove material that correspondingly extends beyond the carrier element prior to the detachment of the wafer layer.

In an alternative embodiment of the method, the seed layer is n-doped or p-doped during the application with a dopant concentration in the range from 1×10¹⁶ cm⁻³ to 5×10¹⁹ cm⁻³, preferably in the range from 1×10¹⁷ cm⁻³ to 3×10¹⁹ cm⁻³, especially in the range from 1×10¹⁸ cm⁻³ to 1×10¹⁹ cm⁻³.

By virtue of doping of the seed layer during epitaxy, it is possible to establish the quality of the seed layer in an improved manner on account of the high purity of the dopant elements. Especially by comparison with a carrier element that has been cut from a block produced by means of zone melting or crystal growing methods, such as the Czochralski method, it is possible to reduce the input of extraneous matter, especially of metals, by a factor of greater than 10, especially greater than 50. A reduced input of extraneous matter leads to an elevated quality of the seed layer and correspondingly also of the wafer layer.

Moreover, extraneous matter can also affect the formation of the carrier layer and the process of porosification, and so a lower input of extraneous matter also has a positive effect here, especially also on the uniformity of formation of the separation layer on the surface.

Moreover, doping of the seed layer enables good electrical contacting of the seed layer of the carrier element during the porosification, which has an advantageous effect on the etching operation.

In an advantageous manner, the dopant elements boron, phosphorus, gallium or arsenic are used for doping of a seed layer composed of silicon or germanium.

The conductivity of the seed layer is preferably within a range between 2 mohm cm and 500 mohm cm, preferably within a range from 5 mohm cm to 25 mohm cm, especially around 15 mohm cm.

A contact layer is preferably applied, formed or disposed on the surface of the carrier substrate remote from the seed layer before, during or after the application of the seed layer.

The contact layer permits good, especially dry, contacting of the carrier element, which is of particular importance for the process of porosification. The properties of the contact layer may be adjusted here appropriately to the respective circumstances independently of the properties of the carrier element, of the carrier substrate and/or of the seed layer. The contact layer preferably has metallic or metal-like electrical properties.

An advantageous configuration of the method has the feature that the contact layer is formed by diffusion of a diffusion layer on the surface of the carrier substrate remote from the seed layer into the carrier substrate, where the diffusion layer is especially formed by a holding element for holding the carrier substrate during method step A2, or is applied prior to method step A2 on the surface of the carrier substrate remote from the seed layer.

The solid-state diffusion enables inexpensive formation of a contact layer even during the production of the seed layer. Thus, there is no need for any further method steps, such as separate arrangement or application of the contact layer.

A further advantageous configuration of the method has the feature that the contact layer has been formed or is formed from polycrystalline semiconductor material, especially from polysilicon.

A polycrystalline material offers the advantage of inexpensive and good dry contacting of the carrier element.

It is preferably possible by means of a polycrystalline contact layer or a highly doped contact layer, especially one doped with the doping element phosphorus, to getter or immobilize impurities, especially from the carrier substrate. The quality of the seed layer can thus be improved further.

Alternatively or additionally, the contact layer is formed or disposed so as to protrude beyond the carrier substrate.

The contact layer preferably has a thickness in the range from 0.1 to 20 μm, especially in the range from 1 to 12 μm. The thickness of the contact layer is especially guided by the function and properties thereof; more particularly, the preferred thickness of the contact layer enables good contacting of the carrier element and sufficient stability.

An alternative configuration of the method has the feature that the seed layer is applied to the carrier substrate with an inhomogeneous layer thickness, where the layer thickness especially increases or decreases at least toward one, preferably toward two, opposite lateral faces of the carrier substrate.

Further preferably, the change in layer thickness toward the lateral faces from the middle of the seed layer may especially be constant.

The formation of an inhomogeneous layer thickness can counter inhomogeneities during the process of porosification, especially inhomogeneities in relation to the current supplied and the electrical field.

The present invention further relates to a carrier element for the production of a wafer layer.

The carrier element comprises a carrier substrate which has especially been formed from silicon, germanium or gallium arsenide, and an epitaxial seed layer applied to at least one surface and at least one lateral face of the carrier substrate, and a separation layer, formed by the porosifying of the at least one surface of the epitaxial seed layer.

The seed layer preferably ensheaths the one surface and all lateral faces of the carrier substrate.

More particularly, the seed layer may be applied to all surfaces and all lateral faces of the carrier substrate and may fully ensheath the carrier substrate.

The carrier substrate can thus be protected from outside influences that affect the reusability of the carrier substrate.

An advantageous configuration of the carrier element has the feature that the seed layer on the at least one surface of the carrier substrate has a layer thickness in the range from 10 μm to 250 μm, preferably in the range from 25 μm to 100 μm, more preferably in the range from 40 μm to 80 μm.

Alternatively or additionally, the seed layer on the at least one lateral face of the carrier substrate has a layer width in the range from 10 μm to 600 μm, preferably in the range from 25 μm to 400 μm, more preferably in the range from 50 μm to 250 μm.

On detachment of the wafer layer from the carrier element, especially as a result of the trimming of the wafer layer to be detached and of the porosification of the carrier element, there can be a reduction in the layer thickness and layer width. An appropriate layer thickness of the carrier element enables the performance of a multitude of cycles of method steps B to D for production of a wafer layer with the same carrier element until attainment of the minimum dimensions of the carrier element.

In an advantageous manner, a contact layer, preferably composed of polycrystalline semiconductor material, especially polysilicon, is disposed on the surface of the carrier substrate remote from the seed layer.

The contact layer can especially be formed by solid-state diffusion from a holding element that holds the carrier element during the production of the seed layer or from a dopant-containing layer applied on a surface of the carrier substrate remote from the seed layer into the carrier substrate. This permits inexpensive production of the contact layer without a separate method step for application or arrangement of the contact layer on the carrier element.

The contact layer permits good contacting of the carrier element, especially during porosification.

The carrier element of the invention preferably finds use in the production of a semiconductor layer by the method of the invention, especially of an advantageous embodiment thereof.

The present invention further relates to an intermediate product in the course of production of a wafer layer.

The intermediate product comprises a carrier element of the invention as detailed above, especially an advantageous embodiment of the carrier element, and an epitaxial wafer layer disposed on the separation layer.

The intermediate product preferably finds use in the production of a semiconductor layer by the method of the invention, especially an advantageous embodiment thereof.

### BRIEF DESCRIPTION OF THE DRAWINGS

Further advantageous features and configurations are elucidated hereinafter with reference to working examples and the figures. The figures show:

FIGS. 1A to 1D one working example of a method of the invention for production of a wafer layer;

FIG. 2 one working example of a carrier element of the invention; and

FIGS. 3A and 3B further working examples of a carrier element of the invention.

### DETAILED DESCRIPTION

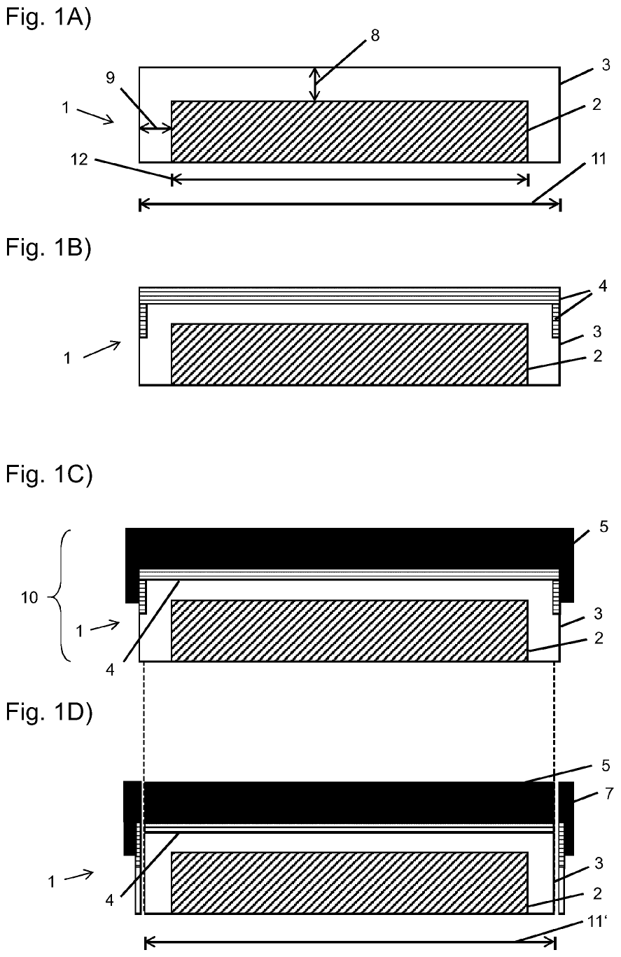

All figures are schematic diagrams that are not true to scale. In the figures, identical reference numerals denote elements that are the same or have the same effect. In FIGS. 1A-1D, 2, and 3A-3B, a surface of a carrier substrate 2 or of a carrier element 1 to which a seed layer 3 is applied is always at the top.

FIGS. 1A to 1D show a process of the invention for producing a wafer layer.

As shown in FIG. 1A, a seed layer 3 was deposited on a carrier substrate 2 provided in a method step A1, in a method step A2, by means of epitaxy to form a carrier element 1 which is used for production of a wafer layer 5. The seed layer 3 fully ensheaths the carrier substrate 2 on an upper surface and the lateral faces. The lower face of the carrier substrate 2 remote from the upper surface is not covered by the seed layer 3.

The carrier substrate 2 is a semiconductor, especially composed of silicon, which has been produced in a zone melting or crystal growing method. The thickness of the carrier substrate 2 is in the range from 250 μm to 1000 μm. The carrier substrate 2 has a square basic shape, the lateral edges of which have a length of 100 mm to 300 mm, especially of 140 to 170 mm. As well as a square basic shape, the carrier substrate 2 may also have a pseudo-square shape with tapered/rounded corners, or a round, oval or rectangular shape.

The carrier substrate 2, in lateral direction, has a dimension 12 adjoined by the layer width 9 of the seed layer 3 on the lateral faces of the carrier substrate 2, such that the carrier element 1 overall has a lateral dimension 11.

The seed layer 3 has been applied with a layer thickness 8 atop the surface of the carrier substrate 2. The layer thickness 8, as shown in FIG. 1A, is essentially identical to the layer width 9.

The seed layer 3 has been applied atop the carrier substrate 2 by means of epitaxy, especially by means of chemical gas phase deposition. By epitaxy, it is possible to form high-quality layers, which is a crucial starting point for the production of correspondingly high-quality seed layers 3. More particularly, by epitaxy, the seed layer 3 can be adjusted to the necessary requirements, especially with regard to crystal quality and electrical properties, for a downstream process.

In a process step B that follows the production of the carrier element 1, a porous separation layer 4 is formed on the surface and at least partly on the lateral edges of the carrier element 1 and hence on the surface and at least partly on the lateral edges of the seed layer 3, as shown in FIG. 1B. The separation layer 4 has a thickness of up to 3 μm, in the present case about 2 μm. The formation of the separation layer 4 on the carrier element 1 is effected by means of etching, especially porosification, and can be conducted, for example, as described in DE 10 2013 219 886 A1. The method described enables formation of the separation layer 4 over the full surface area of the carrier element 1.

In a further method step C, an epitaxial wafer layer 5 is deposited on the separation layer 4 of the carrier element 1. The wafer layer 5 partly overlaps the lateral faces of the carrier element 1 and can extend further even beyond some of the lateral faces of the carrier element 1. The broadened formation of the wafer layer 5 ensures a high quality of the wafer layer 5 virtually up to its edge region. This is shown in FIG. 1C.

The product comprising the carrier element 1 and the wafer layer 5 is also referred to as intermediate product 10.

In a further method step, the intermediate product 10 thus produced, composed of carrier element 1 and wafer layer 5, is trimmed at the lateral faces of the carrier element 1. The trimming removes portions 7 of the wafer layer 5 that protrude beyond the carrier element 1, and possibly also further portions of the wafer layer 5 adhering to the lateral faces of the carrier element 1, as shown in FIG. 1D.

The trimming is effected by a laser beam. Alternatively, the trimming can also be effected by mechanical processing such as sawing or grinding. More particularly, the trimming achieves the effect that portions of the wafer layer 5 adhering to the carrier element 1 are removed, so as to enable reuse of the carrier element 1. However, it is usually necessary for this purpose also to remove a minimal amount of the carrier element 1 at its lateral faces, so as to result in a lateral dimension 11′ lower than the original lateral dimension 11 after method step A.

After the trimming of the intermediate product 10, in a method step D, the wafer layer 5 is detached from the carrier element 1.

The carrier element 1, after the detachment of the wafer layer 5, again undergoes method steps B to D, as shown in FIGS. 1B to 1D, for production of a further wafer layer 5.

A lower lateral dimension 11′ of the carrier element 1 does not adversely affect the production of the wafer layer 5, provided that the carrier element 1 is free of residues of any previously applied wafer layer 5 and the lower lateral dimension 11′ of the carrier element 1 and especially preferably also the thickness of the carrier element 11 is not below a minimum dimension. Therefore, a cycle of method steps B and D is repeated as often as desired until the dimensions of the carrier element 1 are equal to or slightly below the minimum dimensions.

A lower limit for the minimum dimension is the lateral dimension 12 and also the thickness of the carrier substrate 2. As soon as the lateral dimension 11′ approaches the lateral dimension 12 or the corresponding thickness of the carrier element 1 approaches the thickness of the carrier substrate 2, the carrier element 1 is processed by the performance of method step A2 and the resulting new application of a seed layer 3 to the carrier element 1 or the carrier substrate 2.

Prior to the new performance of method step A2 on an already utilized carrier element 1, this carrier element 1 or the carrier substrate 2 may be subjected to a first processing operation, such that the formation of a high-quality seed layer 3 on the carrier element 1 that was already being utilized can in turn be enabled. For this purpose, the carrier element 1 provided for reuse, or the carrier substrate 2, can be processed by mechanical treatment such as polishing or grinding or chemical treatments such as etching or a combination of chemical and mechanical treatment prior to method step A2, such that this especially has a high-quality surface, atop which the seed layer 3 is subsequently applied.

If the dimension 11′ of the carrier element 1 essentially corresponds to the dimensions 12 of the carrier substrate 2, for reprocessing of the carrier element 1, a new seed layer 3 is formed on the previously used carrier substrate 2, such that it is reprocessed to give a carrier element 2 with its original lateral dimension 11, as shown in FIG. 1A. This reprocessed carrier element 1 is then utilized further for the production of wafer layers 5 without having to use a new carrier substrate 2 here. As a result of the reprocessing of the carrier element 1, a carrier substrate 2 can thus be used at least 50 times for the production of wafer layers 5, as shown in FIGS. 1B to 1D.

The layer thickness 8, and also the layer width 9, of the seed layer 3 is within a range from 10 μm to 250 μm, preferably in the range from 25 μm to 100 μm, more preferably in the range from 40 μm to 80 μm. A layer thickness 8, and also layer width 9, of the seed layer 3 as specified above has the advantage of generation of a high-quality seed layer 3 which is also producible within a period which is correspondingly acceptable in terms of the process.

In accordance with the defined parameters such as quality for the production of the wafer layer 5, the carrier substrate 2, and also the seed layer 3, may contain doping or not need any doping.

More particularly, the carrier substrate 2 has n-doping or p-doping with a dopant concentration in the region of less than 5×10¹⁹ cm⁻³, preferably in the region of less than 1×10¹⁸ cm⁻³, more preferably in the region of less than 1×10¹⁷ cm⁻³, most preferably in the region of less than 5×10¹⁵ cm⁻³, in the present case p-doping by means of boron as dopant with a dopant concentration of 1.5×10¹⁶ cm⁻³. The production of doped carrier substrates 2 by means of zone melting or crystal growing methods is associated with the input of extraneous matter into the crystal structure, especially of metallic, oxidic, nitridic or carbidic extraneous matter, and the formation of agglomerates, which ultimately lowers the overall quality and goodness of the carrier substrate 2 by virtue of extraneous matter and a nonuniform distribution of the dopants.

The starting point for high-quality layers is carrier substrates 2 and seed layers 3 that are already of high quality. Therefore, high-quality and therefore usually also high-value substrates should find use as carrier substrates 2, since the quality of the carrier substrate 2 ultimately also has a crucial influence on the quality of the wafer layer 5. Therefore, carrier substrates 2 having only a low dopant concentration preferably find use. The carrier substrates 2, if they are doped, have p-doping, especially with the element boron.

As a result of the much greater frequency of use of a carrier substrate 2 with up to 150 uses or more, the higher initial costs for a higher-quality carrier substrate 2 in the production of the wafer layers 5 are of no consequence, such that a further reduction in costs for the production of a wafer layer 5 is achieved with improved quality.

However, it is especially advantageous in method step B for the formation of the separation 4 when the carrier element 1 has doping. This is enabled in the present case by the doping, especially by p-doping, of the seed layer 3 on which the separation layer 4 is formed by porosification. The seed layer here has a dopant concentration in the range from 1×10¹⁶ cm⁻³ to 5×10¹⁹ cm⁻¹, preferably in the range from 1×10¹⁷ cm⁻³ to 3×10¹⁹ cm⁻³, especially in the range from 1×10¹⁸ cm⁻³ to 1×10¹⁹ cm⁻³, in the present case p-doping with the doping element boron as dopant of 5×10¹⁸ cm⁻³.

The epitaxial formation of the seed layer 3 additionally results in more homogeneous doping of the seed layer with the doping element and with a distinctly reduced input of extraneous matter, especially by up to a factor of 100, since the doping elements or dopants in epitaxy are in a particularly high purity. Moreover, the input of oxygen, which is partly responsible for induced stacking defects in the wafer layer 5, into the crystal structure is also reduced by the epitaxy by up to a factor of 20. The more uniform doping also results in more uniform formation of the separation layer 4 on the seed layer 3, which in turn has a positive effect on the quality of the wafer layer 5 produced thereon.

FIG. 2 shows a particular embodiment of the carrier element 1. The carrier element 1 in turn has a carrier substrate 2 and a seed layer 3, with the seed layer 3 having been applied atop the carrier substrate 2 with a greater layer width 9 compared to the layer thickness 8.

After each production process of a wafer layer 5 in method steps B to D, the lateral dimension 11 of the carrier element 1, and also the layer thickness 8 of the seed layer, is reduced. The lateral dimensions 11′ of the carrier element 1 are reduced especially as a result of the trimming of the wafer layer 5 or of the carrier element 1 for assurance of the complete removal of the wafer layer 5 prior to the production of a further wafer layer 5. The layer thickness 8 of the seed layer 3 also decreases with each etching operation in method step B.

As a result of the trimming, the lateral dimension 11 of the carrier element 1 decreases more significantly with each wafer layer 5 than the layer thickness 8 of the seed layer 3 as a result of the porosification. More particularly, the trimming of the lateral faces of the carrier element is subject to greater fluctuation and also depends on the corresponding trimming device. For reduction of production costs for a wafer layer 5, trimming devices used are especially also those that have a greater tolerance in relation to the removal of material at the lateral faces of the carrier element 1 that are in the range from 2 μm to 20 μm, in the present case about 5 μm. In order to enable a maximum possible number of cycles for production of a wafer layer 5 with a single carrier element 1 prior to processing thereof, therefore, increased formation of the layer width 9 of the seed layer 3 compared to the layer thickness 8 of the seed layer 3 is advantageous.

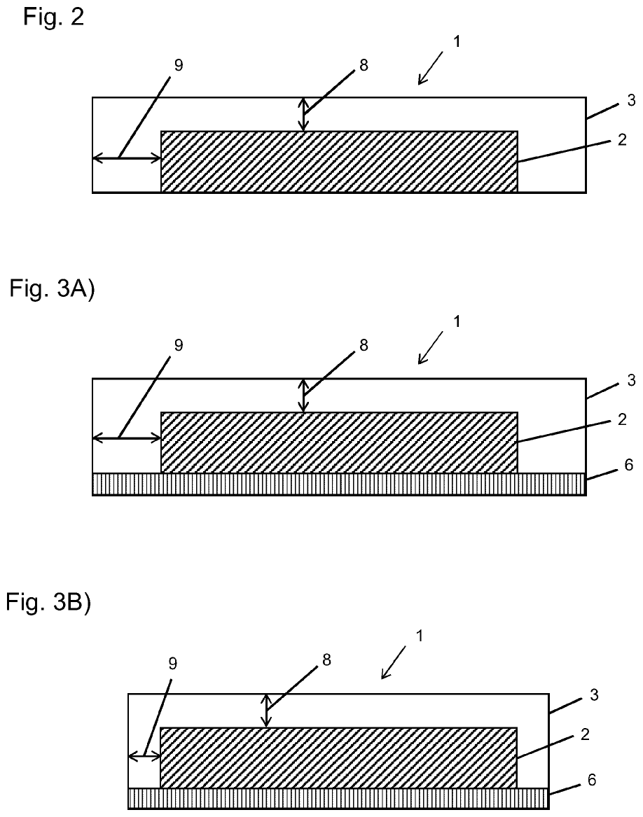

FIGS. 3A and 3B each show a carrier element 1 having a contact layer 6 on the surface of the carrier substrate 1 remote from the seed layer 3.

The contact layer 6, prior to the application of the seed layer 3, has been applied to or bonded to the carrier substrate 2 by means of gas phase deposition or diffusion. Alternatively, application of the contact layer 6 during or after the application of the seed layer 3 is within the scope of the invention. The contact layer 6 is applied prior to method step B, since good contacting of the carrier element 1 is important for the process of porosification in method step B.

The contact layer 6 is formed from a polycrystalline semiconductor material, especially from polysilicon, which enables good dry contactability during the porosification of the carrier element 1. For good contactability, especially good dry contactability, of the contact layer, it has electrical properties at least similar to the electrical properties of a metal.

The lateral dimension of the contact layer 6 corresponds approximately to the lateral dimension 12 of the carrier substrate 2, or even goes beyond the lateral dimension 12 of the carrier substrate 2. More particularly, the lateral dimension of the contact layer 6 may also be less than the lateral dimension 11 of the carrier element 1. The thickness of the contact layer 6 is within a range from 0.1 to 20 μm, in the present case about 10 μm, and is thus well below the thickness of the carrier substrate 2 and is also less than the layer thickness 8.

As shown in FIG. 3A, the contact layer 6 has a greater lateral dimension than the carrier substrate 2, which is identical to the lateral dimension 11 of the carrier element 1. This also results in a distinctly greater layer width 9 compared to the layer thickness 8. During one cycle of method steps B to D, the lateral decrease in size as a result of the trimming of the carrier element 1 and the subsequent detachment of the wafer layer 5 is greater than the reduction in layer thickness 8. It is therefore advantageous to apply the carrier element 1 with a greater layer width 9 compared to the layer thickness 8 on the carrier substrate 1.

The formation of the contact layer 6 over the full area always ensures good, especially dry, contacting irrespective of the reduction in the lateral dimensions 11 of the carrier element 1 after the detachment of a wafer layer 5.

List of Reference Numerals

1 carrier element

2 carrier element

3 seed layer

4 separation layer

5 wafer layer

6 contact layer

7 portion

8 layer thickness

9 layer width

10 intermediate product

11, 11′ dimension of carrier element

12 dimension of carrier substrate

1. A method of producing a wafer layer (5), comprising the following method steps:
A providing a carrier element (1);
B porosifying the carrier element (1) on at least one surface for creation of a separation layer (4);
C epitaxially applying a wafer layer (5) to the separation layer (4) of the carrier element (1); and
D detaching the wafer layer (5) from the carrier element (1),
wherein method steps B to D are repeated at least once with the carrier element (1); and
method step A comprises the further method steps of
A1 providing a carrier substrate (2); and
A2 epitaxially applying a seed layer (3) to at least one surface and at least one lateral face of the carrier substrate (2) for production of the carrier element (1).

2. The method as claimed in claim 1, wherein the seed layer (3) is applied so as to ensheath the one surface and all of the lateral faces of the carrier substrate (2).

3. The method as claimed in claim 1, wherein the carrier substrate (2) and the seed layer (3) have been formed or are formed from silicon, germanium or gallium arsenide.

4. The method as claimed in claim 1, wherein the carrier substrate (2) is n-doped or p-doped, and a dopant concentration is in a region of less than 5×10¹⁹ cm^{31 3}.

5. The method as claimed in claim 1, wherein the seed layer (3) is applied on the at least one surface of the carrier substrate (2) with a layer thickness (8) in a range from 10 μm to 250 μm.

6. The method as claimed in claim 1, wherein the seed layer (3) is dope , during the application with a dopant concentration in a range from 1×10¹⁶ cm⁻³ to 5×10¹⁹ cm⁻.

7. The method as claimed in claim 1, further comprising: applying, forming, or disposing a contact layer (6) on the surface of the carrier substrate (2) remote from the seed layer (3) before, during or after the application of the seed layer (3).

8. The method as claimed in claim 7, wherein the contact layer (6) has been formed or is formed from polycrystalline semiconductor.

9. The method as claimed in claim 7, wherein the contact layer (6) has a thickness in a range from 0.1 to 20 μm.

10. The method as claimed in claim 7, further comprising forming the contact layer (6) by diffusion of a diffusion layer on the surface of the carrier substrate (2) remote from the seed layer (3) into the carrier substrate (2).

11. The method as claimed in claim 1, wherein the seed layer (3) is applied to the carrier substrate (2) with an inhomogeneous layer thickness (8), and the inhomogeneous layer thickness (8) increases or decreases at least toward one, of two opposite ones of the lateral faces of the carrier substrate (2).

12. A carrier element (1) for production of a wafer layer (5), the carrier element comprising:
a carrier substrate (2);
an epitaxial seed layer (3) applied to at least one surface and at least one lateral face of the carrier substrate (2); and
a separation layer (4) formed by porosifying of the at least one surface of the epitaxial seed layer (3).

13. The carrier element (1) as claimed in claim 12, wherein the seed layer (3) on the at least one surface of the carrier substrate (2) has a layer thickness (8) in a range from 10 μm to 250 μm.

14. The carrier element (1) as claimed in claim 12, wherein the seed layer (3) has a greater layer width (9) than layer thickness (8) on the at least one surface.

15. The carrier element (1) as claimed in claim 12, further comprising a contact layer (6) disposed on the surface of the carrier substrate (2) remote from the seed layer (3).

16. An intermediate product (10) comprising the carrier element (1) as claimed in claim 12 and an epitaxial wafer layer (5) disposed on the separation layer (4).

17. The method as claimed in claim 1, wherein the seed layer (3) is applied on the at least one lateral face of the carrier substrate (2) with a layer width (9) in a range from 10 μm to 600 μm.

18. The method as claimed in claim 7, wherein material the contact layer (6) is formed or disposed so as to protrude beyond the carrier substrate (2).

19. The method of claim 10, wherein the diffusion layer is formed by a holding element for holding the carrier substrate (2) during method step A2, or is applied prior to method step A2 on the surface of the carrier substrate (2) remote from the seed layer (3).

20. The carrier element (1) as claimed in claim 12, wherein the seed layer (3) on the at least one lateral face of the carrier substrate (2) has a layer width (9) in the range from 10 μm to 600 μm.
